(19) United States
(12) Patent Application Publication
(10) Pub. No.: US 2010/0072624 A1
(43) Pub. Date: Mar. 25, 2010

(54) METAL INTERCONNECTION

(75) Inventor: Yan-Hsiu Liu, Tainan City (TW)

Correspondence Address: NORTH AMERICA INTELLECTUAL PROPERTY CORPORATION, P.O. BOX 506, MERRIFIELD, VA, 22116, US

(73) Assignee: United Microelectronics Corp., Hsinchu (TW)

(21) Appl. No.: 12/233,930

(22) Filed: Sep. 19, 2008

(51) Int. Cl. H01L 23/532

(52) U.S. Cl. 257/763; 257/E23.163

(57) ABSTRACT

A metal interconnection including a substrate, a first conductive structure, a second conductive structure, a complex plug and a plug is provided. The substrate includes a first region and a second region. The first conductive structure is disposed on the first region. The second conductive structure is disposed on the second region. The complex plug is disposed on the first conductive structure and includes a tungsten layer and a plurality of insulator columns, wherein an extended direction of each of the insulator columns is perpendicular to a surface of the substrate and the tungsten layer is electrically connected with the first conductive structure. The plug is disposed on the second conductive structure and electrically connected with the second conductive structure.

### BACKGROUND OF THE INVENTION

1. Field of the Invention

The present invention relates to a semiconductor device, and particularly relates to a metal interconnection.

2. Description of Related Art

A metal oxide semiconductor device (MOS device) is a very widely-applied semiconductor device. Generally speaking, in the current fabricating process of a metal oxide semiconductor device, the current density of a device is increased to reduce the Rdson thereof, so as to enhance the reliability of the device. The current density of a device is in direct proportion to the total current flowing through this device.

However, in a semiconductor device provided with high current, such as a high voltage device, a power MOS device, and a lateral diffusion MOS device, it is difficult to fabricate a large-sized plug or to dispose a plurality of plugs in an area, so that the total current flowing through the device is limited. For instance, it is difficult to gapfill a large-sized opening formed in the fabricating process of the large-sized plug. Additionally, dishing effect usually occurs when a chemical-mechanical polishing process is performed to remove the metal material outside the large-sized opening. The space for disposing the plugs is increased as the number of the plugs in an area is increased, so that the size of the device is hard to minimize. In summary, the current density of the device is hard to increase due to the problems described above. In addition, the plugs may be damaged when high current is flowing through therein, and consequently the device is damaged.

### SUMMARY OF THE INVENTION

The present invention provides a metal interconnection, which comprises a complex plug for greatly improving the current density of a device.

The present invention provides a metal interconnection, which comprises a substrate, a first conductive structure, a second conductive structure, a complex plug, and a plug. The substrate comprises a first region and a second region. The first conductive structure is disposed on the first region. The second conductive structure is disposed on the second region. The complex plug is disposed on the first conductive structure and comprises a tungsten layer and a plurality of insulator columns disposed in the tungsten layer, wherein an extended direction of each of the insulator columns is perpendicular to a surface of the substrate, and the tungsten layer is electrically connected with the first conductive structure. The plug is disposed on the second conductive structure and electrically connected with the second conductive structure.

In an embodiment of the present invention, the tungsten layer is reticular.

In an embodiment of the present invention, the insulator columns are rectangular, square, hexagonal, cross-like or circular.

In an embodiment of the present invention, the area of the complex plug is larger than 2.25 um².

In an embodiment of the present invention, the first region is a high voltage device region.

In an embodiment of the present invention, the first region is a power MOS device region.

In an embodiment of the present invention, the first region is a LDMOS device region.

In an embodiment of the present invention, a material of the plug comprises tungsten.

In an embodiment of the present invention, the metal interconnection further comprises a conductive layer disposed on the complex plug and electrically connected with the first conductive structure through the complex plug.

In an embodiment of the present invention, the conductive layer is a conductive line.

In an embodiment of the present invention, an extended direction of the conductive line is parallel to the surface of the substrate.

In an embodiment of the present invention, the conductive layer is a bonding pad.

The metal interconnection of the present invention comprises a complex plug and a plug. The complex plug comprises a tungsten layer and a plurality of insulator columns disposed in the tungsten layer, wherein an extended direction of each of the insulator columns is perpendicular to a surface of the substrate. A large amount of current flows through the complex plug, such that the complex plug greatly enhances the current density of the device. Hence, the complex plug is adapted for connecting a device with high current. The plug is adapted for connecting a device which does not require high current. In other words, the complex plug or the plug may be disposed based on the electric characteristic of a device to be connected, so as to improve the reliability and integration of the device.

To make the above features and advantages of the present invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are cross-sectional views illustrating a process flow for manufacturing a metal interconnection according to an embodiment of the present invention.

FIG. 2 is a top view illustrating a portion of the substrate in FIG. 1B.

FIG. 3 is a top view illustrating a portion of the substrate in FIG. 1D.

FIGS. 4A through 4D are top views illustrating a complex plug according to an embodiment of the present invention.

### DESCRIPTION OF EMBODIMENTS

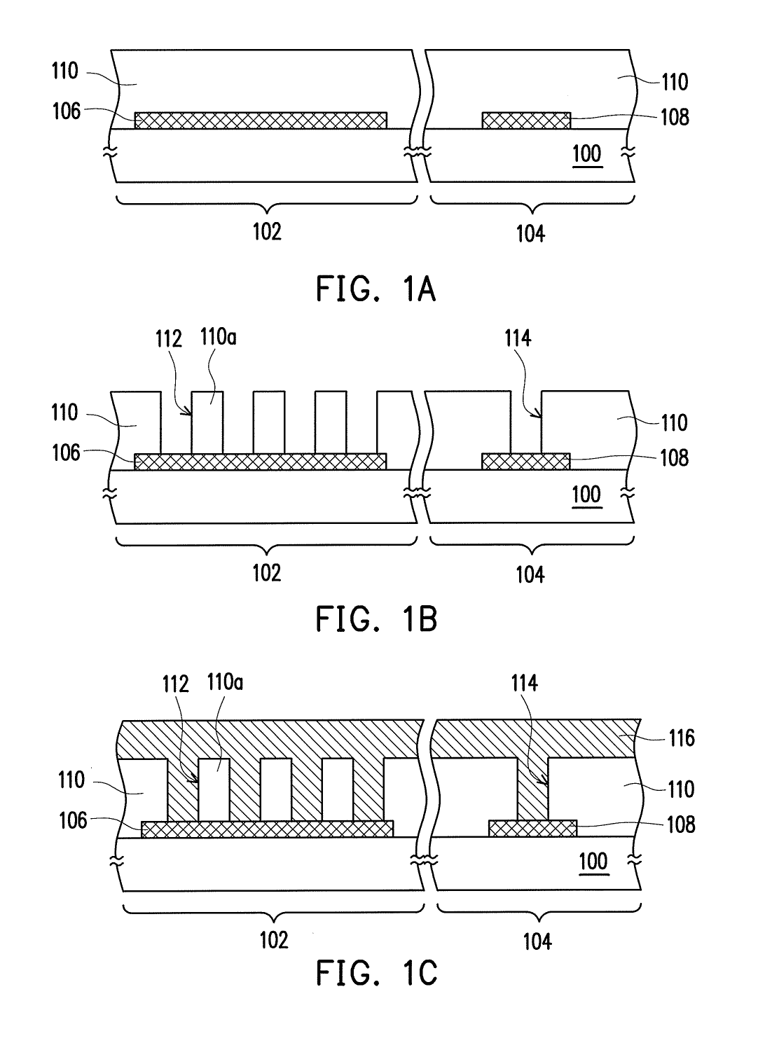

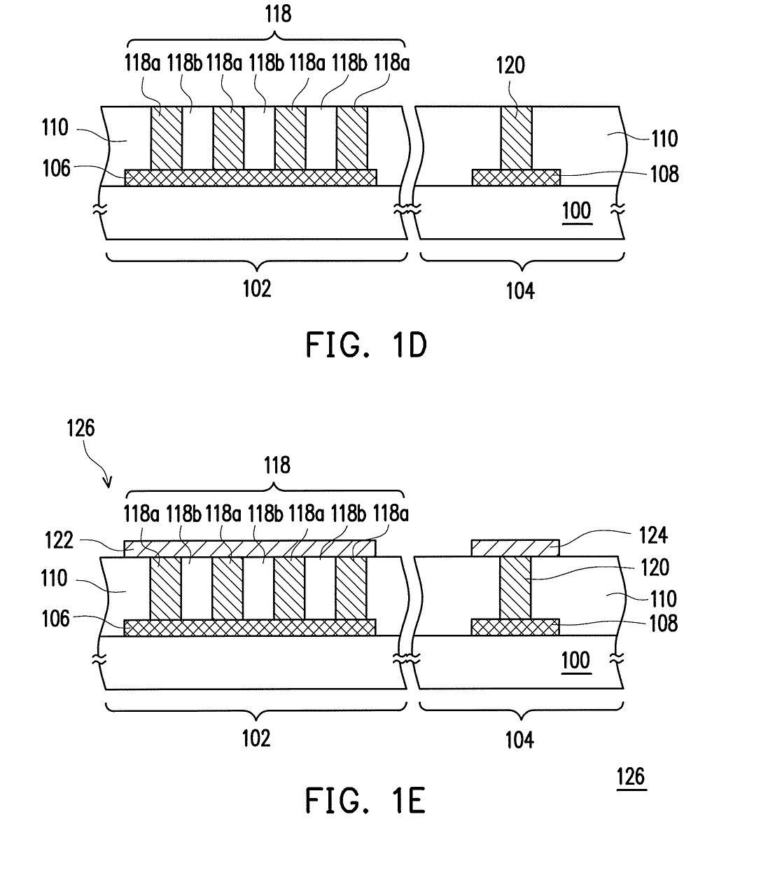

FIGS. 1A through 1E are cross-sectional views illustrating a process flow for manufacturing a metal interconnection according to an embodiment of the present invention.

Referring to FIG. 1A, a substrate 100 is provided. In this embodiment, the substrate 100 comprises a first region 102 and a second region 104. The first region 102 is, for example, disposed with a device having high current, and the first region 102 may be a high voltage device region, a power MOS device region, or a LDMOS device region; the second region 104 is, for example, disposed with a device which does not require high current, and the second region 104 may be a general device region. A first conductive structure 106 and a second conductive structure 108 are respectively disposed on the first region 102 and the second region 104, and a material of the first conductive structure 106 or the second conductive structure 108 may be a conductive material, such as polysilicon, polycide, aluminum, tungsten, or titanium.

Then, a dielectric layer 110 is formed on the substrate 100 to cover the first conductive structure 106 and the second conductive structure 108. A material of the dielectric layer 110 is, for example, silicon oxide, silicon nitride or a low dielectric constant material (with a dielectric constant k<4). The low dielectric constant material, for example, comprises an inorganic material, such as hydrogen silsesquioxane (HSQ) or fluorinated silicate glass (FSG), or an organic material, such as fluorinated poly-(arylene ether) (Flare), poly-(arylene ether) (SILK) or parylene. A method for forming the dielectric layer 110 is, for example, a chemical vapor deposition process.

FIG. 2 is a top view illustrating a portion of the substrate in FIG. 1B. Referring to FIGS. 1B and 2, openings 112 and 114 are respectively formed in the dielectric layer 110 on the first region 102 and the second region 104, so as to expose the first conductive structure 106 and the second conductive structure 108. Herein, a portion of the dielectric layer 110 on the first region 102 is formed into insulator columns 110a. In this embodiment, the openings 112 and 114 are, for example, formed in one photolithography process. In other words, the openings 112 and 114 may be formed by using the same photomask.

Referring to FIG. 1C, a tungsten material layer 116 is then formed on the dielectric layer 110 to fill the openings 112 and 114. A method for forming the tungsten material layer 116 is, for example, a chemical vapor deposition process or a sputtering process. In this embodiment, the insulator columns 110a increase the total surface area of the opening 112. Thereby, the gap filling ability of the tungsten material layer 116 to the opening 112 is improved.

Next, referring to FIG. 1D, for instance, a chemical-mechanical polishing process or a etchback process is performed to remove the tungsten material layer 116 outside the openings 112 and 114, so as to respectively form a complex plug 118 and a plug 120 on the first region 102 and the second region 104. Herein, the complex plug 118 is electrically connected with the first conductive structure 106, and the plug 120 is electrically connected with the second conductive structure 108. In this embodiment, because a plurality of insulator columns 110a (referring to FIG. 1C) is formed on the first region 102, a plug having a large area can be prevented, so as dishing effect which occurs during the removal of the tungsten material layer 116 outside the opening 112 can be prevented and the surface of the complex plug 118. In other words, the surface of the complex plug 118 formed by the method provided in the invention is flatter. Additionally, in this embodiment the complex plug 118 and the plug 120 are, for example, simultaneously formed, and the plug 120 is formed by tungsten. However, in other embodiments, the plug 120 may be formed by other conductive materials instead of tungsten.

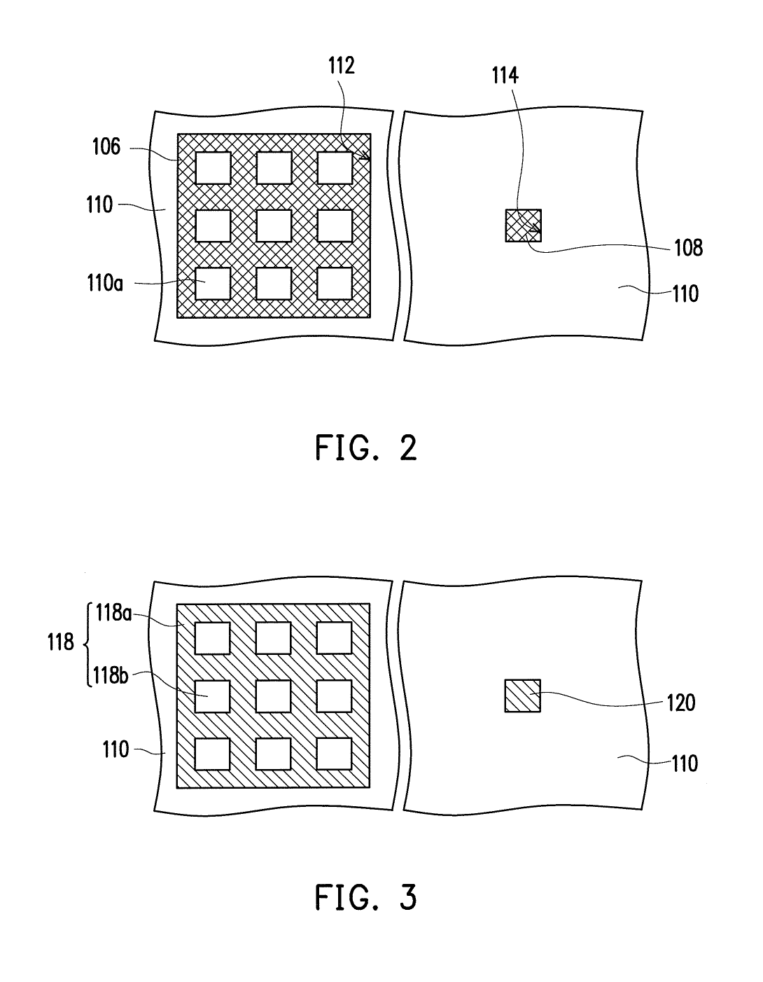

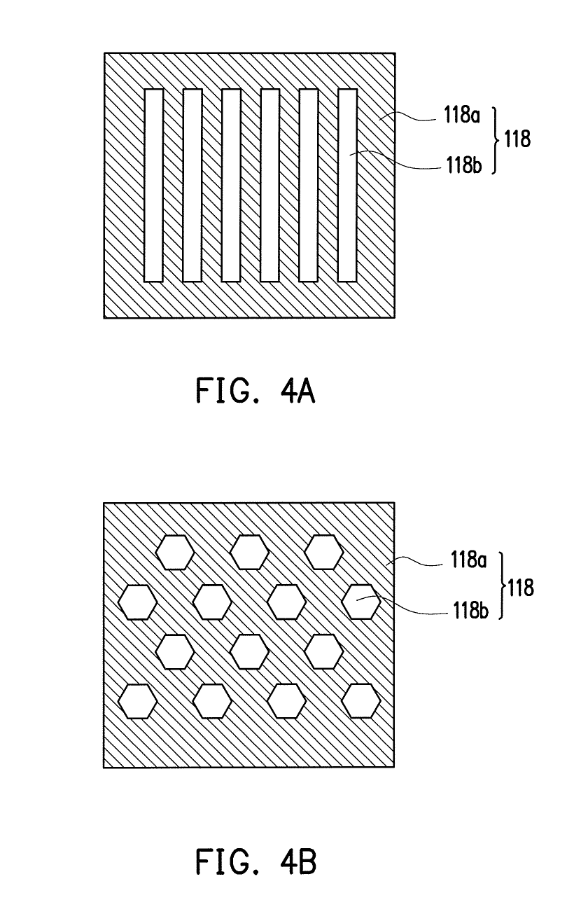

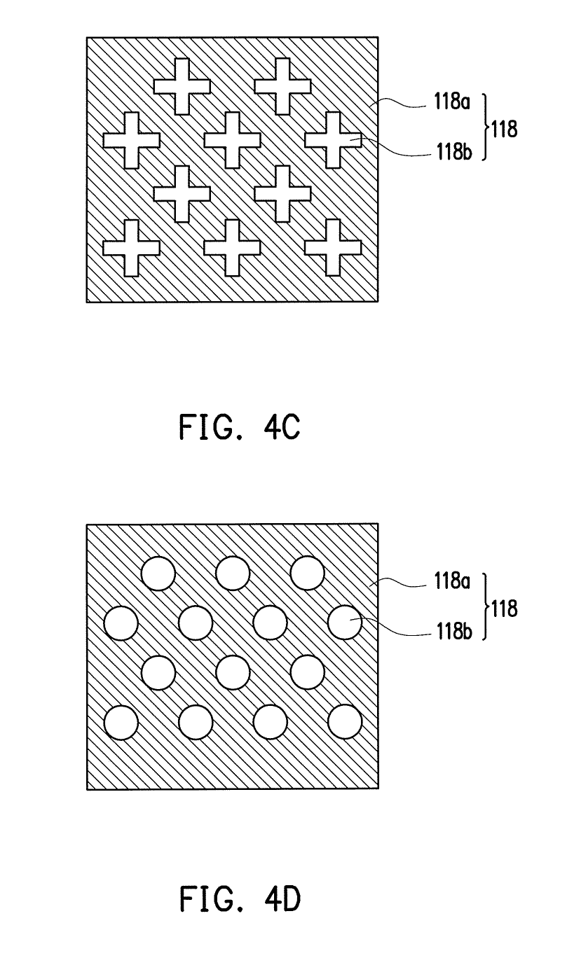

FIG. 3 is a top view illustrating a portion of the substrate in FIG. 1D. Referring to FIGS. 1D and 3, the complex plug 118 is a contact plug or a via plug. The complex plug 118 comprises a tungsten layer 118a and insulator columns 118b. An extended direction of each of the insulator columns 118b is perpendicular to a surface of the substrate 100, and the tungsten layer 118a is electrically connected with the first conductive structure 106. The area of the complex plug 118 (the area in the top view of FIG. 3) is, for example, larger than 2.25 um². In this embodiment, the tungsten layer 118a is reticular, and the insulator columns 118b are square, for instance. However, the present invention is not limited thereto. In other embodiments, as shown in FIGS. 4A through 4D, the insulator columns 118b of the complex plug 118 may also be rectangular, precisely hexagonal, cross-like, or circular. Hence, the tungsten layer 118a may be in a different reticular form. Moreover, in an embodiment (not shown), the insulator columns may have more than two forms. In other words, the present invention does not limit the forms of the tungsten layer 118a and the insulator columns 118b of the complex plug 118. Additionally, the number of the insulator columns 118b in this embodiment is 9, for example. However, the present invention does not limit the number of the insulator columns 118b.

Referring to FIG. 1E, a first conductive layer 122 and a second conductive layer 124 are formed on the dielectric layer 110 to be electrically connected with the complex plug 118 and the plug 120 respectively. To be more specific, the first conductive layer 122 is electrically connected with the first conductive structure 106 through the complex plug 118, and the second conductive layer 124 is electrically connected with the second conductive structure 108 through the plug 120. In this embodiment, the first conductive layer 122 and the second conductive layer 124 are, for example, conductive lines. A material thereof is, for example, a conductive material such as polysilicon, polycide, aluminum, tungsten, or titanium. In other embodiments, the first conductive layer and the second conductive layer may also be bonding pads. It is noted that an extended direction of the insulator columns 118b in the complex plug 118 is perpendicular to the surface of the substrate 100, and an extended direction of the conductive line (the first conductive layer 122) is parallel to the surface of the substrate 100. In other words, the extended direction of each of the insulator columns in the complex plug is perpendicular to the extended direction of the conductive line (the first conductive layer) connected therewith.

To conclude, the metal interconnection of the present invention comprises the complex plug and the plug. The complex plug comprises the tungsten layer and a plurality of insulator columns disposed in the tungsten layer, and an extended direction of each of the insulator columns is perpendicular to the surface of the substrate. A large amount of current flows through the tungsten layer of the complex plug, and thereby the complex plug greatly improves the current density of the device to furnish the device with tolerance to high current. In other words, the complex plug is adapted for being connected with high current devices such as a high voltage device, a power MOS device, or a LDMOS device. The plug is adapted for being connected with devices which do not require high current.

Hence, the complex plug or the plug may be disposed based on the electric characteristic of the device to be connected, so as to improve the reliability and integration of the device. Furthermore, the complex plug and the plug can be formed in one fabricating process. Consequently, the number of the photomasks required in the fabricating process does not need to be increased, and the production costs can be effectively controlled. Additionally, the structure of the complex plug can prevent the difficulty in gapfilling the opening or dishing effect which occur during the fabricating process, so as to maintain the electric characteristic of the complex plug. Moreover, the complex plug can increase the current density of the devices, so that the size of wafer can be minimized and integration of devices can be increased.

Although the present invention has been disclosed by the above embodiments, they are not intended to limit the present invention. Persons with ordinary knowledge in the art may make some modifications and variations without departing from the spirit and scope of the present invention. Therefore, the protection range of the present invention falls in the appended claims.

1. A metal interconnection, comprising:
a substrate, comprising a first region and a second region;
a first conductive structure disposed on the first region;
a second conductive structure disposed on the second region;
a complex plug disposed on the first conductive structure, comprising a tungsten layer and a plurality of insulator columns disposed in the tungsten layer, wherein an extended direction of each of the insulator columns is perpendicular to a surface of the substrate, and the tungsten layer is electrically connected with the first conductive structure; and
a plug disposed on the second conductive structure and electrically connected with the second conductive structure.

2. The metal interconnection as claimed in claim 1, wherein the tungsten layer is reticular.

3. The metal interconnection as claimed in claim 1, wherein the insulator columns are rectangular, square, hexagonal, cross-like or circular.

4. The metal interconnection as claimed in claim 1, wherein the area of the complex plug is larger than 2.25 um2.

5. (canceled)

6. The metal interconnection as claimed in claim 1, wherein the first region is a power MOS device region.

7. (canceled)

8. The metal interconnection as claimed in claim 1, wherein a material of the plug comprises tungsten.

9. The metal interconnection as claimed in claim 1, further comprising a conductive layer disposed on the complex plug and electrically connected with the first conductive structure through the complex plug.

10. The metal interconnection as claimed in claim 9, wherein the conductive layer is a conductive line.

11. The metal interconnection as claimed in claim 10, wherein an extended direction of the conductive line is parallel to a surface of the substrate.

12. The metal interconnection as claimed in claim 9, wherein the conductive layer is a bonding pad.
